(19) United States
(12) Patent Application Publication
(10) Pub. No.: US 2010/0081219 A1
(43) Pub. Date: Apr. 1, 2010

(54) METHOD OF MANUFACTURING A SEMICONDUCTOR DEVICE

(76) Inventors: Tomoya TANAKA, Toyama (JP); Shin-ichi Imai, Osaka (JP)

Correspondence Address: MCDERMOTT WILL & EMERY LLP, 600 13TH STREET, NW, WASHINGTON, DC, 20005-3096, US

(21) Appl. No.: 12/563,574

(22) Filed: Sep. 21, 2009

(30) Foreign Application Priority Data
Sep. 30, 2008 (JP) 2008-254657

(51) Int. Cl. H01L 21/66

(52) U.S. Cl. 438/17; 438/14; 438/692; 257/E21.499; 257/E21.531

(57) ABSTRACT

In the method of manufacturing a semiconductor device, first, values of diffusion parameters of a semiconductor device are acquired in a middle of manufacturing the semiconductor device. Next, a target value of another diffusion parameter to be determined by a processing implemented in a subsequent process of the semiconductor device manufacturing process is calculated. The another diffusion parameter is calculated by substituting the acquired values of diffusion parameters and a desired value of an electrical characteristic of the semiconductor device into a predetermined prediction expression. The prediction expression is an expression showing a corresponding relationship between the electrical characteristic and a plurality of types of diffusion parameters of the semiconductor device. Subsequently, processing conditions for the processing implemented in the subsequent process to realize the target value is determined. Then, the processing to the semiconductor device in the subsequent process is implemented under the determined processing conditions.

### CROSS-REFERENCE TO RELATED APPLICATION

The disclosure of Japanese Patent Application No. 2008-254657 filed Sep. 30, 2008 including specification, drawings and claims is incorporated herein by reference in its entirety.

### BACKGROUND OF THE INVENTION

1. Field of the Invention

The present invention relates to a method of manufacturing a semiconductor device, and particularly relates to a method of manufacturing a semiconductor device where electrical characteristics of semiconductor devices to be formed on different wafers can be made uniform.

2. Description of the Related Art

In a manufacturing process of semiconductor devices, various apparatuses, such as an exposure apparatus, an implantation apparatus, a thermal treatment apparatus, a film-forming apparatus, an etching apparatus or a polishing apparatus (hereafter, referred to as semiconductor manufacturing apparatus), are used. Processing variations caused by fluctuation of an apparatus condition of such semiconductor manufacturing apparatus affects the electrical characteristics of semiconductor devices. In particular, in a recent semiconductor device composed of minute patterns, an effect on the electrical characteristics become obvious as a decrease in a production yield of the semiconductor device even with the fluctuation of the apparatus condition within specifications of the semiconductor manufacturing apparatus. In order to control such fluctuations of the electrical characteristics caused by the processing variations of the semiconductor manufacturing apparatus, in the manufacturing process of the semiconductor device, in each process, an advanced process control (APC) for controlling diffusion parameters, such as finished dimensions or film thickness, to be predetermined target values is implemented.

Further, a technique where a prediction expression to predict the electrical characteristics from all characteristic values (diffusion parameters, such as a measured value of a finished pattern dimension or a measured film thickness value, and apparatus parameters, such as processing condition in the semiconductor manufacturing apparatus used for processing) regarding the processing (wafer treatment) of the semiconductor device is prepared, values of the electrical characteristics are predicted using the prediction expression in each process step (for example, see Published Japanese Translation No. 2005-536887 of PCT International Publications for Patent Publication). With such a technique, during manufacturing, when there is no actual data of the characteristic values, an initial set value is entered into the prediction expression, and electrical characteristics in each process step are predicted by replacing the initial set value with the actual data when collecting the actual data. Then, when the predicted value of the electrical characteristics calculated from the prediction expression greatly differs from a target value of the electrical characteristics, processing to adjust the electrical characteristics are implemented in the subsequent process to enable adjusting the electrical characteristics by modifying processing conditions. It is believed that the electrical characteristics of the semiconductor device can become constant with this implementation.

### SUMMARY OF THE INVENTION

In the APC, in order to control the diffusion parameters in each process step with lesser variation to be closer to target values, it is necessary to always understand fluctuation of processing characteristics, such as an etching rate or polishing rate, according to state variation of the semiconductor manufacturing apparatus. Therefore, in semiconductor manufacturing apparatus where this type of APC is implemented, processing characteristic fluctuation is detected by inspecting a physical quantity indicating processing results on a processed wafer. However, it is not realistic to inspect all processed wafers in the semiconductor manufacturing apparatus from a cost standpoint. In actuality, the processing characteristic fluctuation is detected by inspection of a part of the processed wafers (monitoring wafer). Consequently, the processing characteristic fluctuation of the semiconductor manufacturing apparatus cannot be detected for each wafer, and even if APC is implemented, the diffusion parameters have a certain degree of variation. Therefore, even if the APC is implemented, it would be difficult to completely control all of the diffusion parameters that affect the electrical characteristics at a target value. As a result, the electrical characteristics of the semiconductor device vary according to the variation of the diffusion parameters and production yield is decreased.

Further, in the technique disclosed in the prior document, the prediction expression is modeled using all characteristic values regarding the wafer processing, and the diffusion parameters and the apparatus parameters are handled in the same dimension (apposition). Further, since the prediction expression is a statistical model and it is not generalized, the prediction accuracy is not always guaranteed. Therefore, it is difficult to control the electrical characteristics according to the prediction expression.

The present invention has been proposed by taking such problem into consideration, and has the objective of providing a method of manufacturing a semiconductor device where electrical characteristics are predicted with high accuracy, and the electrical characteristics are controlled to become constant using the prediction expression.

In order to accomplish this objective, the present invention has adopted the following means. The present invention realizes uniformity of electrical characteristics of semiconductor devices to be formed on different wafers using an electrical characteristic prediction expression showing an electrical characteristic with diffusion parameters reflecting a post-processing configuration, such as a film thickness to be deposited on a semiconductor substrate, finished dimensions of fabricated patterns, or the like. Conventionally, it is a newly-discovered finding by the inventors of the present application that results of electrical measurement implemented at a time of completing entire processes or at a time of completing a specific process can be predicted with high accuracy by the electrical characteristic prediction expression.

A method of manufacturing a semiconductor device of a first aspect relating to the present invention is applied to a manufacturing process of a semiconductor device including a plurality of processes. In this method of manufacturing a semiconductor device, first, values of diffusion parameters of a semiconductor device are acquired in a middle of manufacturing the semiconductor device. Next, in order to control an electrical characteristic of the semiconductor device using APC technology, a target value of another diffusion parameter to be determined by a processing implemented in a subsequent process of the semiconductor device manufacturing process is calculated. This another diffusion parameter is calculated by substituting the acquired values of the diffusion parameters and a desired value of the electrical characteristic into a predetermined electrical characteristic prediction expression. Here, the electrical characteristic prediction expression is an expression showing a corresponding relationship between the electrical characteristic of the semiconductor device and a plurality of types of diffusion parameters of the semiconductor device. Subsequently, processing conditions for the processing implemented in the subsequent process to realize the target value is determined. Then, the processing to the semiconductor device in the subsequent process is implemented under the determined processing conditions.

According to this method of manufacturing a semiconductor device, a semiconductor device having desired electrical characteristics can be manufactured, and electrical characteristic variations among wafers can be inhibited. Therefore, a decrease in the production yield can be prevented.

In the method of manufacturing a semiconductor device, the diffusion parameter values of the semiconductor device may be directly-measured measurement values, and may be calculated values. In other words, at least one diffusion parameter value of the semiconductor device can be acquired by substituting values of apparatus parameter of a manufacturing apparatus acquired in a processing of the semiconductor device in the manufacturing apparatus into a predetermined diffusion parameter calculation expression. A value of the at least one diffusion parameter of the semiconductor device is determined by the processing implemented in the manufacturing apparatus. The diffusion parameter calculation expression is an expression showing a corresponding relationship between the at least one diffusion parameter and the apparatus parameters of the manufacturing apparatus. Further, the apparatus parameters are parameters of the state of the manufacturing apparatus implementing the processing to the semiconductor device.

In such method, even if the diffusion parameter values cannot be actually measured, diffusion parameter values can be acquired for each wafer, and the electrical characteristic can be individually predicted for each wafer.

For example, the plurality of processes can include a process of forming a concave portion in an insulating film formed on a semiconductor substrate, a process of depositing a conductive film on the insulating film where the concave portion is formed and embedding the concave portion with the conductive film, and a process of forming a wiring by removing the conductive film on the insulating film except for the concave portion using polishing. In this case, the diffusion parameters of which values are acquired include a depth of the concave portion, an opening width of the concave portion and a film thickness of the insulating film before the polishing. The electrical characteristic includes an electrical resistance of the wiring. The another diffusion parameter of which value is determined by the processing in the subsequent process includes a film thickness of the insulating film after the polishing. The processing conditions include a polishing time. Furthermore, the wiring includes a via contact that electrically connects wirings formed by interposing the interlayer insulating film.

A method of manufacturing a semiconductor device of a second aspect relating to the present invention is applied to a manufacturing process of a semiconductor device which includes a process of forming a concave portion in an insulating film formed on a semiconductor substrate, a process of depositing a conductive film on the insulating film where the concave portion is formed and embedding the concave portion with the conductive film, and a process of removing the conductive film on the insulating film except for the concave portion using a polishing apparatus. In this method of manufacturing a semiconductor device, when a specific semiconductor substrate is processed in the etching apparatus, values of apparatus parameters of the etching apparatus are acquired. Next, a depth of a concave portion formed in an insulating film of the specific semiconductor substrate is calculated. The depth of the concave portion is calculated by substituting the acquired values of the apparatus parameters into a predetermined concave portion depth calculation expression. Here, the concave portion depth calculation expression is an expression showing a corresponding relationship between the apparatus parameters of the etching apparatus and the depth of the concave portion formed in the insulating film. Subsequently, a polishing rate of the polishing apparatus is calculated. The polishing rate is calculated by substituting values of apparatus parameters of the polishing apparatus acquired in an already-implemented polishing in the polishing apparatus into a predetermined polishing rate calculation expression. Here, the polishing rate calculation expression is an expression showing a corresponding relationship between the apparatus parameters of the polishing apparatus and the polishing rate. Further, a polishing time to be applied to the specific semiconductor substrate in the polishing apparatus is calculated from the calculated polishing rate and a film thickness of a conductive film deposited onto the insulating film of the specific semiconductor substrate. Then, in the polishing apparatus, the specific semiconductor substrate is polished according to the calculated polishing time. When this polishing, values for the apparatus parameters of the polishing apparatus are acquired. A post-polishing residual film thickness of the insulating film on the specific semiconductor substrate is calculated from the film thickness of the conductive film deposited onto the insulating film on the specific semiconductor substrate and a polishing rate calculated by substituting the values of the apparatus parameters of the polishing apparatus acquired in the polishing of the specific semiconductor substrate into the polishing rate calculation expression. After the post-polishing residual film thickness is calculated, an electrical resistance value of a wiring formed on the specific semiconductor substrate is calculated. The electrical resistance value is calculated by substituting the post-polishing residual film thickness calculated for the specific semiconductor substrate and the depth of the concave portion calculated for the specific semiconductor substrate into a predetermined electrical characteristic prediction expression. Here, the electrical characteristic prediction expression is an expression showing a corresponding relationship among the depth of the concave portion, the post-polishing residual film thickness and the electrical resistance. After the electrical resistance value is calculated, whether the calculated electrical resistance value is within the predetermined specification range is determined. As a result of determination, in a case that the calculated electrical resistance value is lower resistance beyond the specification range, an additional polishing amount is calculated based on the electrical characteristic prediction expression, and the specific semiconductor substrate is polished according to the additional polishing amount in the polishing apparatus.

According to this method of manufacturing a semiconductor device, a semiconductor device having a desired electrical resistance can be manufactured, and wiring resistance variations among wafers can be inhibited. As a result, a decrease in the production yield can be inhibited. Further, a part of irregular wafers can be recovered.

A method of manufacturing a semiconductor device in a third aspect relating to the present invention is applied to a manufacturing process of a semiconductor device which includes a process of forming a concave portion in an insulating film formed on a semiconductor substrate using an etching apparatus, a process of depositing a conductive film on the insulating film where the concave portion is formed and embedding the concave portion with the conductive film, and a process of removing the conductive film on the insulating film except for the concave portion using a polishing apparatus. In this method of manufacturing a semiconductor device, when a specific semiconductor substrate is processed in the etching apparatus, values for apparatus parameters of the etching apparatus are acquired. Next, a depth of a concave portion formed in an insulating film on the specific semiconductor substrate is calculated. The depth of the concave portion is calculated by substituting the acquired values of the apparatus parameters into a predetermined concave portion depth calculation expression. Here, the concave portion depth calculation expression is an expression showing a corresponding relationship between the apparatus parameters of the etching apparatus and the depth of the concave portion formed in the insulating film. Subsequently, a polishing rate of the polishing apparatus is calculated. The polishing rate is calculated by substituting values of apparatus parameters of the polishing apparatus acquired in an already-implemented polishing in the polishing apparatus into a predetermined polishing rate calculation expression. Here, the polishing rate calculation expression is an expression showing a corresponding relationship between the apparatus parameters of the polishing apparatus and the polishing rate. Further, a polishing time to be applied to the specific semiconductor substrate in the polishing apparatus is calculated from the calculated polishing rate and a film thickness of a conductive film deposited onto the insulating film of the specific semiconductor substrate. A post-polishing residual film thickness of the insulating film on the specific semiconductor substrate is predicted from the calculated polishing rate and the film thickness of the conductive film deposited onto the insulating film on the specific semiconductor substrate. An electrical resistance value of a wiring to be formed on the specific semiconductor substrate in the case of applying the calculated polishing time is predicted from the predicted post-polishing residual film thickness on the specific semiconductor substrate and the depth of the concave portion calculated for the specific semiconductor substrate. The predicted electrical resistance value is calculated by substituting the post-polishing residual film thickness and the depth of the concave portion into a predetermined electrical characteristic prediction expression. Here, the electrical characteristic prediction expression is an expression showing a corresponding relationship among the depth of the concave portion, the post-polishing residual film thickness and the electrical resistance. After the predicted value of the electrical resistance is calculated, whether the predicted electrical resistance value is within the predetermined specification range is determined. As a result of the determination, in a case that the predicted electrical resistance value is within the specification range, the specific semiconductor substrate is polished according to the calculated polishing time in the polishing apparatus. Further, in a case that the predicted electrical resistance value is beyond the specification range as a result of the determination, a corrected polishing amount to realize an electrical resistance value within the specification range is calculated based on the electrical characteristic prediction expression. Then, a polishing time is newly calculated from the corrected polishing amount and the polishing rate, and the specific semiconductor substrate is polished in the polishing apparatus according to the newly calculated polishing time.

According to this method of manufacturing a semiconductor device, a semiconductor device having a desired electrical resistance can be manufactured, and wiring resistance variations among wafers can be inhibited. As a result, a decrease in the production yield can be inhibited. Further, any irregular wafers can be recovered.

In this method of manufacturing a semiconductor device, procedures below can be further implemented. First, at a time of the polishing of the specific semiconductor substrate in the polishing apparatus, values for apparatus parameters of the polishing apparatus are acquired. Next, a post-polishing residual film thickness of the insulating film on the specific semiconductor substrate is calculated from the film thickness of the conductive film deposited onto the insulating film on the specific semiconductor substrate and a polishing rate newly calculated by substituting the values of the apparatus parameters of the polishing apparatus acquired in the polishing of the specific semiconductor substrate into the polishing rate calculating expression. An electrical resistance value of a wiring formed on the specific semiconductor substrate is calculated by substituting the calculated post-polishing residual film thickness for the specific semiconductor substrate and the calculated depth of the concave portion for the specific semiconductor substrate into the electrical characteristic prediction expression. Then, whether the electrical resistance value calculated after the polishing is within the predetermined specification range is determined. With this configuration, when there is a great divergence between the predicted electrical resistance value and the actual electrical resistance value of a wafer after the polishing, such wafer can be detected.

In addition, in the method of manufacturing a semiconductor device, as a result of determining whether the electrical resistance value calculated after the polishing is within the predetermined specification range, in a case that the electrical resistance value calculated after the polishing is low resistance beyond the specification range, an addition polishing amount is calculated based on the electrical characteristic prediction expression and the specific semiconductor substrate is polished in the polishing apparatus according to the additional polishing amount. With this configuration, wiring resistance variations among wafers can be further inhibited.

As described above, according to the present invention, the method of manufacturing a semiconductor device where electrical characteristics are predicted with high accuracy and the electrical characteristics are controlled to become constant using the prediction expression.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are process cross sectional views showing manufacturing processes of a semiconductor device in each embodiment relating to the present invention.

FIG. 2 is a process cross sectional view showing a manufacturing process of a semiconductor device in each embodiment relating to the present invention.

FIG. 3 is a process cross sectional view showing a manufacturing process of a semiconductor device in each embodiment relating to the present invention.

FIG. 4 is a flow chart showing a method of manufacturing a semiconductor device in the first embodiment relating to the present invention.

FIG. 5 is a configuration diagram showing a manufacturing system of a semiconductor device in the first embodiment relating to the present invention.

FIG. 6 is a configuration diagram showing a manufacturing system of a semiconductor device in the second embodiment relating to the present invention.

FIG. 7 is a flow chart showing a method of manufacturing a semiconductor device in the second embodiment relating to the present invention.

FIG. 8 is a configuration diagram showing a manufacturing system of a semiconductor device in the third embodiment relating to the present invention.

FIG. 9 is a flow showing a method of manufacturing a semiconductor device in the third embodiment relating to the present invention.

FIG. 10 is a configuration diagram showing a manufacturing system of a semiconductor device in the fourth embodiment relating to the present invention.

FIG. 11 is a flow chart showing a method of manufacturing a semiconductor device in the fourth embodiment relating to the present invention.

FIG. 12 is a flow chart showing a method of manufacturing a semiconductor device in the fifth embodiment relating to the present invention.

### DETAILED DESCRIPTION OF PREFERRED EMBODIMENTS

Each embodiment of the present invention is explained in detail hereafter with reference to the drawings. In each embodiment, the present invention is embodied by a case of a wiring embedded and formed in an interlayer insulating film of a semiconductor device. Furthermore, hereafter, via-holes and trenches may be named generically as “concave portion”.

### First Embodiment

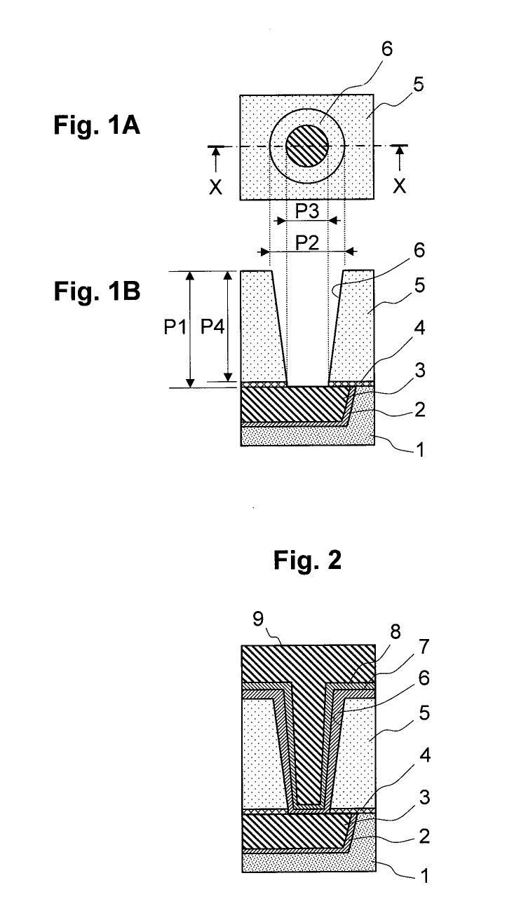

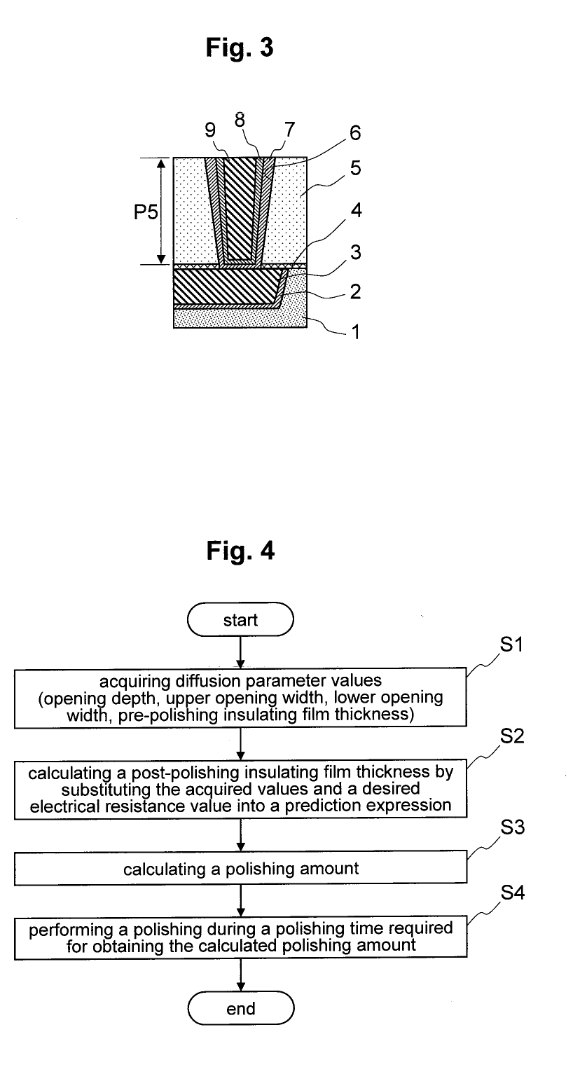

In a first embodiment, a method for determining a processing condition (fabricating condition) using an electrical characteristic prediction expression of a semiconductor device. Prior to the explanation, first, an example of a structure of a semiconductor device where the prediction expression is applied is briefly explained along with a manufacturing process thereof. FIGS. 1A to 3 are diagrams showing a formation process of a wiring in a semiconductor device having an embedded wiring. Furthermore, FIG. 1A is an enlarged plane view showing a periphery of a concave portion where the wiring is embedded, and FIG. 1B is a cross sectional view along the X-X line shown in FIG. 1A. Further, FIGS. 2 and 3 show only cross sectional views corresponding to the X-X line of FIG. 1A.

First, as shown in FIGS. 1A and 1B, a first interlayer insulating film layer 1 made of a silicon oxide film and the like is deposited on a semiconductor substrate (not illustrated) where a semiconductor element is formed at a predetermined position. Next, a trench where a lower layer wiring is embedded is formed in the first interlayer insulating film 1. A barrier film 2 made of tantalum nitride (TaN) and the like, and an underlaying wiring material 3 made of copper or copper alloy are deposited onto the first interlayer insulating film 1 where the trench is formed in sequence from the lower layer. When a surface of the first interlayer insulating film 1 is exposed by polishing the barrier film 2 and the underlayer wiring material 3 using chemical mechanical polishing (CMP), the lower layer wiring where the barrier film 2 and the underlaying wiring material 3 are embedded into the trench is formed.

Next, a stopper film 4 made of a silicon nitride film and the like and a second interlayer insulating film 5 made of a silicon oxide film and the like, for covering the first interlayer insulating film 1 where the lower wiring is formed, are deposited in sequence from the lower layer. A concave portion is formed at a predetermined position of the second interlayer insulating film 5 by applying a lithography technology and an etching technology. Here, a via-hole 6 is formed as a concave portion. Furthermore, in FIG. 1A, a planar configuration of the concave portion is circular; however, it can be rectangular. Further, the concave portion to be formed in the second interlayer insulating film 5 is not limited to the via-hole 6, but may be a trench where an embedded wiring is formed.

Subsequently, after a barrier film 7 and a seed film 8 are formed within the via-hole 6 using a sputtering method as shown in FIG. 2 in sequence from the lower layer, a copper plating film 9 is formed on the entire surface of the substrate including the concave portion by copper plating. After the copper plating film 9 is formed, for example, the copper plating film 9, the seed film 8 and the barrier film 7 deposited on the second interlayer insulating film 5 other than the via-hole 6 are removed by CMP. With this removal, a surface of the copper plating film 9 filled into the via-hole 6 and a surface of the second interlayer insulating film 5 become the same plane. Thus, as shown in FIG. 3, an embedded wiring (via contact) made from the barrier film 7, the seed film 8 and the copper plating film 9 is formed within the via-hole 6.

In the wiring embedded into the concave portion formed as described above, an electrical resistance, which is one of electrical characteristics of the wiring, changes by depending upon a depth of the concave portion, an opening width of the concave portion (an opening diameter in a case that the concave portion is a via-hole), and a film thickness of the interlayer insulating film where the concave portion is formed.

For example, in the via-hole shown in FIGS. 1A to 3, the opening diameter of the via-hole 6 becomes gradually smaller toward the lower side from the upper side in general. Further, even with the via-holes 6 whose a top diameter of the opening is the same, when the film thickness of the interlayer insulating film (Here, the second interlayer insulating film 5) where the via-holes 6 is formed is different, a bottom diameter of the opening will never be the same. Therefore, in the via contact structure formed as described above, the electrical resistance (an electrical resistance of a via plug, a contact resistance between the via plug and the lower layer wiring and a contact resistance between the via plug and an upper layer wiring) changes by depending upon the depth of the concave portion, the opening width of the upper and lower sides of the concave portion, and the film thickness of the interlayer insulating film where the concave portion is formed, etc.

Then, in this embodiment, a prediction expression of the electrical resistance R using a opening depth P1, an upper side opening width P2, a lower side opening width P3, a pre-polishing insulating film thickness P4 and a post-polishing insulating film thickness P5 as explanatory variables, which are parameters showing a geometric configuration of the concave portion, is prepared in advance, and a processing condition (a polishing amount herein) for obtaining a desired electrical resistance value is determined using the prediction expression. For example, the electrical resistance R of the via contact or the trench wiring formed in the interlayer insulating film can be expressed with a synthesizing expression of diffusion parameters P1 to P5, which are typical values showing a post-processing shape of a fabricated pattern. For example, as the synthesizing expression, an expression (1) mentioned below can be adopted. The expression (1) is a prediction expression of the electrical resistance R. Furthermore, coefficients k₁, k₂, k₃, k₄ and k₅ and a constant K in the expression (1) can be experimentally defined in advance. In other words, with regard to the actually-formed via contact or trench wiring, the opening depth P1, the upper side opening width P2, the lower side opening width P3, the pre-polishing insulating film thickness P4, the post-polishing insulating film thickness P5 and the electrical resistance R are measured, and the coefficients k₁ to k₅ and the constant K can be defined by a multiple linear regression analysis using the measured values which are acquired with regard to a plurality of times of processing.

R=k₁×P1+k₂×P2+k₃×P3+k₄×P4+k₅×P5+K (1)

Furthermore, the electrical resistance R of the via-contact assumed from a physical model or the trench wiring per unit length can be expressed with the expression (2) below according to specific electrical resistance ρ and a cross-sectional area S of the via or the trench wiring in a direction vertical to a current pathway.

R [symbol] ρ/S (2)

In the expression (2), since the specific electrical resistance ρ is a unique value to a wiring material, it can be regarded as a constant value. Therefore, since the electrical resistance R depends upon only the cross-sectional area S, the electrical resistance R can be described with a combination of diffusion parameters (the diffusion parameters P1 to P5 in the expression (1)) relating to the cross-sectional area S. Furthermore, it is the most accurate to assume the cross-sectional area S of the copper wiring from the measured value of the finished dimensions; however, since it is general to process with the accuracy of target value ±approximately 20% in the semiconductor device manufacturing, even when the electrical resistance R is expressed with a linier model such as the expression (1) instead of the cross-sectional area S, sufficient accuracy can be obtained within the above range. In particular, using a linear model such as the expression (1), it becomes possible to predict the electrical resistance of a wiring with any configuration (electrical resistance of a via contact or electrical resistance of a trench wiring) only by changing the coefficients k₁ to k₅ and the constant K without changing the configuration of the prediction expression.

When the polishing amount for obtaining a desired electrical resistance value is predicted using the prediction expression shown in the expression (1), the opening depth P1, the upper side opening width P2, the lower side opening width P3 and the pre-polishing insulating film thickness P4 are measured at a point in time when the concave portion (via-hole 6 in FIGS. 1A and 1B) has been formed as shown in FIGS. 1A and 1B. The post-polishing insulating film thickness P5 can be calculated by substituting these measured values and the desired electrical resistance value (target value) into the expression (1). The post-polishing insulating film thickness P5 is a film thickness of the interlayer insulating film (the second interlayer insulating film 5 in FIG. 3) in which the concave portion is formed at a time of completing to polish a conductor embedded into the concave portion. Furthermore, in a case that the concave portion is the via-hole 6, since the opening depth P1 and the pre-polishing insulating film thickness P4 are substantially the same values, the pre-polishing insulating film thickness P4 may be used as a substitute for the opening depth P1, which is difficult to be measured. In the meantime, when the concave portion is a trench for a wiring, because the opening depth P1 is not always the same value as the pre-polishing insulating film thickness P4, both the opening depth P1 and the pre-polishing insulating film thickness P4 are measured. It is preferable that these dimensions are measured from an electrical characteristic measuring pattern, such as process check module (PCM) for examining electrical characteristics of the wiring formed on the wafer. However, these dimensions may be measured from a dimension measuring pattern and the like formed in a different region from a region of the electrical characteristic measuring pattern.

Next, a method of manufacturing a semiconductor device for providing uniform electrical characteristics among different wafers is explained using such electrical characteristic prediction expression. FIG. 4 is a flow chart showing procedures for manufacturing a semiconductor device using an electrical characteristic prediction expression in this embodiment. Furthermore, here, the electrical characteristics are electrical resistance of the trench wiring.

As shown in FIG. 4, first, when the concave portion is formed in the second interlayer insulating film 5, the opening depth P1, the upper side opening width P2, the lower side opening width P3 and the pre-polishing insulating film thickness P4 are measured (Step S1 in FIG. 4). A predicted value of the post-polishing insulating film thickness P5 which provides a desired electrical resistance value is calculated by substituting the measured values and the desired electrical resistance value (target value) into the expression (1) (Step S2 in FIG. 4). In this case, the polishing amount (polished film thickness) to be realized in CMP for the purpose of the desired electrical resistance value can be calculated from an expression, (post-polishing insulating film thickness P5)−(pre-polishing insulating film thickness P4) (Step S3 in FIG. 4). Then, the CMP is executed during a polishing time required for polishing the calculated polished film thickness (Step S4 in FIG. 4). The electrical resistance values of corresponding trench wirings among different wafers can be constant. Furthermore, the polishing time is determined according to a polishing rate of a polishing apparatus (CMP apparatus).

Furthermore, in the above description, an example to make the electrical resistance of the copper wiring in the damascene structure constant is explained, and electrical characteristics of various PCMs (for example, large-scale via-chain, capacity between wirings or the like) can be constant by the similar technique, and electrical characteristics of semiconductor devices formed on different wafers can be uniformed. Furthermore, in prediction expressions indicating other electrical characteristics, diffusion parameters to be used as explanatory variables (P1 to P5 in the expression (1)) may be appropriately selected diffusion parameters having high correlation with each target electrical characteristic by a variable determination method, such as a multiple classification analysis, variable increase and decrease method or the like.

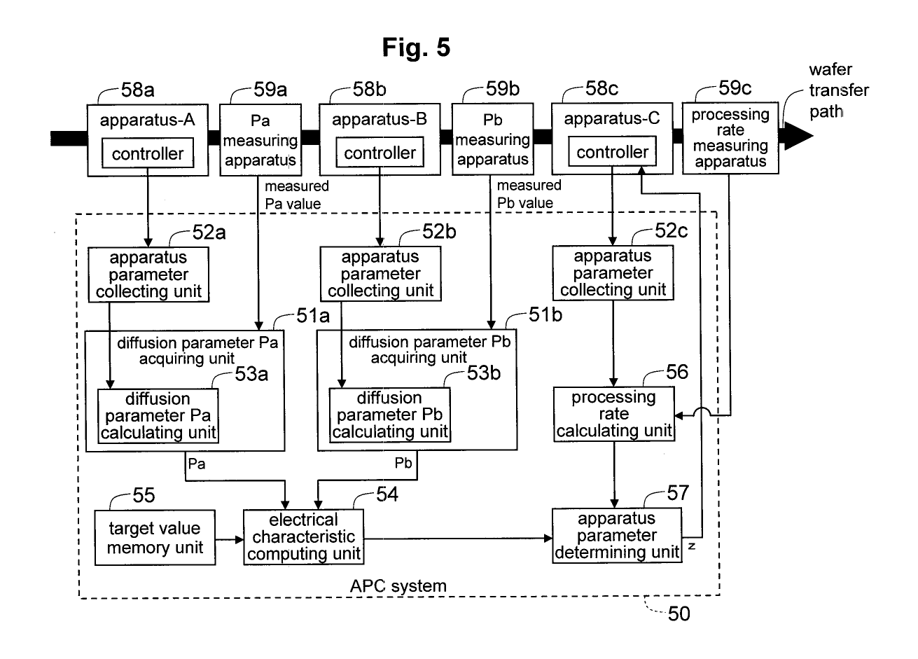

FIG. 5 is a configuration diagram showing one example of a generalized semiconductor manufacturing system for realizing the above described method of manufacturing a semiconductor device for providing uniform electrical characteristics. The semiconductor manufacturing system comprises a semiconductor manufacturing apparatus A (hereafter, referred to as ‘apparatus-A 58a’) for processing a semiconductor substrate (hereafter, referred to as wafer), a semiconductor manufacturing apparatus B (hereafter, referred to as ‘apparatus-B 58b’), a semiconductor manufacturing apparatus C (hereafter, ‘apparatus-C 58c’) and an APC system 50. Here, a wafer is processed in order of the apparatus-A 58a, the apparatus-B 58b and the apparatus-C 58c. Further, explanatory variables in an electrical characteristic prediction expression for predicting a specific electrical characteristic are a diffusion parameter Pa, a diffusion parameter Pb and a diffusion parameter Pc. The diffusion parameter Pa is determined according to a wafer processing in the apparatus-A 58a, the diffusion parameter Pb is determined according to a wafer processing in the apparatus-B 58b, and the diffusion parameter Pc is determined according to a wafer processing in the apparatus-C 58c. Further, a value of the diffusion parameter Pc is predicted in order to obtain a desired electrical characteristic from the electrical characteristic prediction expression, and a wafer processing according to the predicted value is realized in the apparatus-C 58c.

When a wafer is processed in the apparatus-A 58a, a post-processing shape caused by processing in the apparatus-A 58a is inspected by a Pa measuring apparatus 59a, and a measured value of the diffusion parameter Pa is acquired. Subsequently, the wafer is processed in the apparatus-B 58b, and a measured value of the diffusion parameter Pb is acquired by a Pb measuring apparatus 59b. Here, the APC system 50 comprises a diffusion parameter Pa acquiring unit 51a and a diffusion parameter Pb acquiring unit 51b. The diffusion parameter Pa acquiring unit 51a acquires a measured value of the diffusion parameter Pa from the Pa measuring apparatus 59a, and the diffusion parameter Pb acquiring unit 51b acquires a measured value of the diffusion parameter Pb from the Pb measuring apparatus 59b.

An electrical characteristic computing unit 54 acquires the diffusion parameters Pa from the diffusion parameter Pa acquiring unit 51a, acquires the diffusion parameters Pb from the diffusion parameter Pb acquiring unit 51b and acquires a desired electrical characteristic value from a target value memory unit 55. Then, the electrical characteristic computing unit 54 enters them into a pre-registered electrical characteristic prediction expression. The electrical characteristic computing unit 54 calculates a value of the diffusion parameter Pc for obtaining the desired electrical characteristic value, and enters the calculated diffusion parameter Pc into an apparatus parameter determining unit 57. Furthermore, in this embodiment, the desired electrical characteristic value is pre-registered in the target value memory unit 55.

In the meantime, a processing rate calculating unit 56 enters a value for a processing rate, which directly contributes to a determination of a value for the diffusion parameter Pc in the processing implemented in the apparatus-C 58c, into the apparatus parameter determining unit 57. The processing rate is used for determining a processing condition to be implemented in the apparatus-C 58c in order to realize the diffusion parameter Pc calculated by the electrical characteristic computing unit 54. For example, in a case that the apparatus-C 58c is a polishing apparatus and the diffusion parameter Pc is a post-polishing film thickness of a film to be polished, the processing rate is a polishing rate. Further, for example, in a case that the apparatus-C 58c is an etching apparatus and the diffusion parameter Pc is a post-etching film thickness of a film to be etched, the processing rate is an etching rate. In addition, in a case that the apparatus-C 58c is a film-forming apparatus and the diffusion parameter Pc is a formed film thickness, the processing rate is a film formation rate. Not particularly limited, but in this embodiment, the processing rate calculating unit 56 calculates the processing rate using a so-called virtual metrology technology for predicting the processing rate, such as the etching rate or the polishing rate to be acquired from an inline examination by a processing rate measuring apparatus 59c, using data used for a management of the apparatus. In other words, the processing rate is calculated based on a corresponding relationship between the apparatus parameters of the apparatus-C 58c acquired by an apparatus parameter collecting unit 52c via a controller of the apparatus-C 58c and measurement results by the processing rate measuring apparatus 59c. Furthermore, values for the apparatus parameters of the apparatus-C 58c used for the calculation of the processing rate are the latest values showing an apparatus condition of the apparatus-C 58c (for example, apparatus parameters acquired at a time of processing implemented immediately before).

The apparatus parameter determining unit 57 calculates an apparatus parameter z of the apparatus-C 58c based on the value of the diffusion parameter Pc calculated by the electrical characteristic computing unit 54 and the processing rate calculated by the processing rate calculating unit 56 so as to realize the calculated diffusion parameter Pc in the processing by the apparatus-C 58c. The apparatus parameter determining unit 57 enters the calculated apparatus parameter z into a controller of the apparatus-C 58c. Then, a target wafer is processed by the apparatus-C 58c where the apparatus parameter z is set. For example, in a case that the apparatus-C 58c is a polishing apparatus and the diffusion parameter Pc is a post-polishing film thickness of a film to be polished and the processing rate is a polishing rate, the apparatus parameter determining unit 57 calculates a polishing time as the apparatus parameter z.

As described above, according to this embodiment, even if each of the diffusion parameters affecting the specific electrical characteristic varies, processing to be realized the desired electrical characteristic can be implemented in the subsequent process step. As a result, a semiconductor device having the desired electrical characteristic can be manufactured, and the electrical characteristic variations between wafers can be inhibited. Therefore, a decrease in the production yield can be prevented.

In the explanation above, the diffusion parameter Pc for obtaining the desired electrical characteristic is calculated using the measured values of diffusion parameters Pa and Pb; however, it is not essential that the diffusion parameters Pa and Pb are measured values, but calculated values can also be used. Such calculated value, for example, can be calculated using a diffusion parameter calculation expression expressed with a synthesizing expression of the apparatus parameters. For example, in a case that the processing result (diffusion parameter Pb) by the apparatus-B 58b can be expressed with the synthesizing expression of the apparatus parameters of the apparatus-B 58b, the diffusion parameter Pb can be obtained using the apparatus parameters acquired at a the time of processing by the apparatus-B 58b. In this case, the diffusion parameter Pc for obtaining the desired electrical characteristic can be predicted without measuring the diffusion parameter Pb by the Pb measuring apparatus 59b after the processing. Further, in a case that the diffusion parameter Pa can be expressed with the synthesis expression of the apparatus parameters of the apparatus-A 58a, the diffusion parameter Pc for obtaining the desired electrical characteristic can be predicted using the calculated value of the diffusion parameter Pa without measuring the diffusion parameter Pa by the Pa measuring apparatus 59a after the processing.

As such synthesizing expression of the apparatus parameters for calculating a diffusion parameter, for example, the expression (3) below can be used. The expression (3) is a synthesizing expression expressing the diffusion parameter Pa using the apparatus parameters p1 to pn of the apparatus-A 58a, coefficients a1 to an and constant b.

Pa=a1×p1+a2×p2 . . . +an×pn+b (3)

Furthermore, in the expression (3), the apparatus parameters p1 to pn of the apparatus-A 58a may be measured values acquired at a specific timing, and also may be statistical values. The statistical values are, for example, average value, median value, standard deviation, dispersion or range (maximum value−minimum value) based on the apparatus parameters acquired a plurality times during one processing. In this case, the coefficients a1 to an and the constant b can be defined by a multiple linear regression analysis using each statistical value of the apparatus parameters acquired throughout a plurality of times of processing and measured values of the diffusion parameters Pa on the processing where the statistical value of each apparatus parameter is acquired. Further, the apparatus parameters to be used as the explanatory variables p1 to pn in the expression (3) may be appropriately selected apparatus parameters having high correlation with the diffusion parameters Pa by a variable determining method, such as multiple classification analysis, variable increase and decrease method or the like. Furthermore, for the calculation expression of the diffusion parameter Pa, not limited to a first order polynomial expression, but a quadratic function, exponent function and logarithmic function using apparatus parameters may be used.

When such diffusion parameter calculation expression is used, as shown in FIG. 5, the diffusion parameter Pa acquiring unit 51a comprises a diffusion parameter Pa calculating unit 53a, and the diffusion, parameter Pb acquiring unit 51b comprises a diffusion parameter Pb calculating unit 53b. The diffusion parameter Pa calculating unit 53a calculates the diffusion parameter Pa, which is a processing result in the processing where apparatus parameters are acquired, based upon the apparatus parameters of the apparatus-A 58a acquired by an apparatus parameter collecting unit 52a via a controller of the apparatus-A 58a and the above described diffusion parameter calculating expression. Similarly, the diffusion parameter Pb calculating unit 53b calculates the diffusion parameter Pb, which is a processing result in the processing where apparatus parameters are acquired, based upon the apparatus parameters of the apparatus-B 58b acquired by an apparatus parameter collecting unit 52b via a controller of the apparatus-B 58b and the predetermined diffusion parameter calculating expression regarding the apparatus-B 58b. According to this configuration, as described above, the diffusion parameter Pc for obtaining the desired electrical characteristic can be predicted without actually measuring the diffusion parameters Pa and Pb after each processing in the apparatus-A 58a and the apparatus-B 58b.

In addition, the APC system 50 may be further comprise a diffusion parameter Pc calculating unit for calculating the diffusion parameter Pc according to the processing rate calculated by the processing rate calculating unit 56 and the processing time set to the wafer to be processed. Here, the calculated diffusion parameter Pc shows a processing result to be realized by the processing with the set processing time. In this configuration, configuring that the diffusion parameter Pc calculated by the diffusion parameter Pc calculating unit is entered into the electrical characteristic computing unit 54, it becomes possible to predict the electrical characteristic after processing by the apparatus-C 58c before the processing is implemented by the apparatus-C 58c.

In the manufacturing process of a semiconductor device, from viewpoints of a manufacturing lead time and inspection cost, it is difficult to perform measurements for acquiring the finished dimensions on all processed wafers, and acceptance sampling is often implemented to a part of a plurality of wafers in a lot. Even in this case, the diffusion parameters for each wafer can be acquired by adopting the configuration to calculate the diffusion parameters based on the apparatus parameters acquired at a time of the processing for each wafer.

Furthermore, in FIG. 5, it is configured such that the diffusion parameters Pa and Pb depend on the processing in the apparatus-A 58a and the apparatus-B 58b, respectively. However, it may be configured that a plurality of diffusion parameters is determined by one semiconductor manufacturing apparatus. Further, any number of diffusion parameters may be used for the above prediction. In addition, in the above-mentioned example, the configuration where the diffusion parameter Pc to be determined by the processing in the apparatus-C 58c is predicted according to the diffusion parameter Pb to be determined by the processing in the apparatus-B 58b and the diffusion parameter Pa to be determined by the processing in the apparatus-A 58a is exemplified, and each diffusion parameter used for the above prediction may be determined by processing in each of three or more semiconductor manufacturing apparatuses. In addition, all diffusion parameters used for the prediction may be determined by processing in one semiconductor manufacturing apparatus.

### Second Embodiment

In a second embodiment, in addition to the technique to unify the electrical characteristics explained in the first embodiment, a technique to predict results of electrical characteristic examination (WET: Wafer Electric Test or PCM measurement) to be implemented at a time of completing an entire processes for the wafer or at a time of completing a specific process by using the unification technique and to recover a wafer to be defective in the electrical characteristic examination is explained. In other words, in this embodiment, in a semiconductor manufacturing apparatus that can actually adjust a value of a specific parameter by changing processing conditions, the processing is implemented under processing conditions where the diffusion parameter is equal to the predicted value and the electrical characteristic after the processing is predicted according to the electrical characteristic prediction expression. Then, whether the electrical characteristic will be defect on the electrical characteristic examination is determined based on the predicted electrical characteristic. Furthermore, in this embodiment, the present invention is embodied by a case of applying to a unification of electrical resistances of corresponding embedded wirings in a semiconductor devices formed on the different wafers.

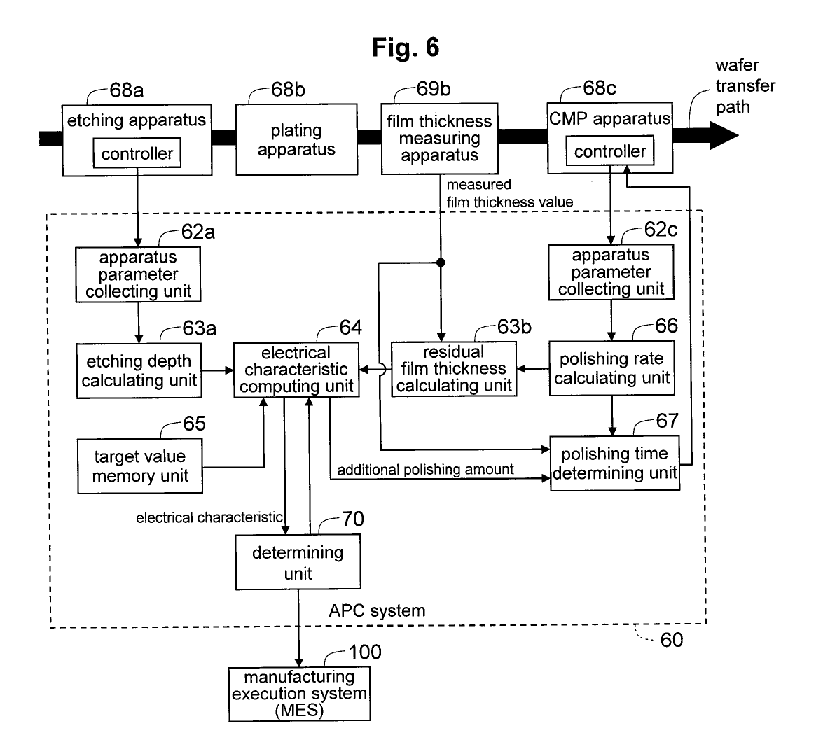

FIG. 6 is a configuration diagram showing a semiconductor manufacturing system to realize a method of manufacturing a semiconductor device in this embodiment. As shown in FIG. 6, the semiconductor manufacturing system comprises an etching apparatus 68a, a plating apparatus 68b, a CMP apparatus 68c and an APC system 60. The etching apparatus 68a forms a concave portion in an interlayer insulating film formed on the wafer (see FIG. 1B). The plating apparatus 68b forms a conductive film on the interlayer insulating film including the concave portion so as to fill the concave portion (see FIG. 2). The CMP apparatus 68c polishes and removes the conductive film formed by the plating apparatus 68b except for the concave portion. Furthermore, a film thickness measuring apparatus 69b shown in between the plating apparatus 68b and the CMP apparatus 68c measures a film thickness of the conductive film (including a barrier film and a seed film) deposited on the interlayer insulating film. Furthermore, in this embodiment, copper is deposited by the plating apparatus 68b.

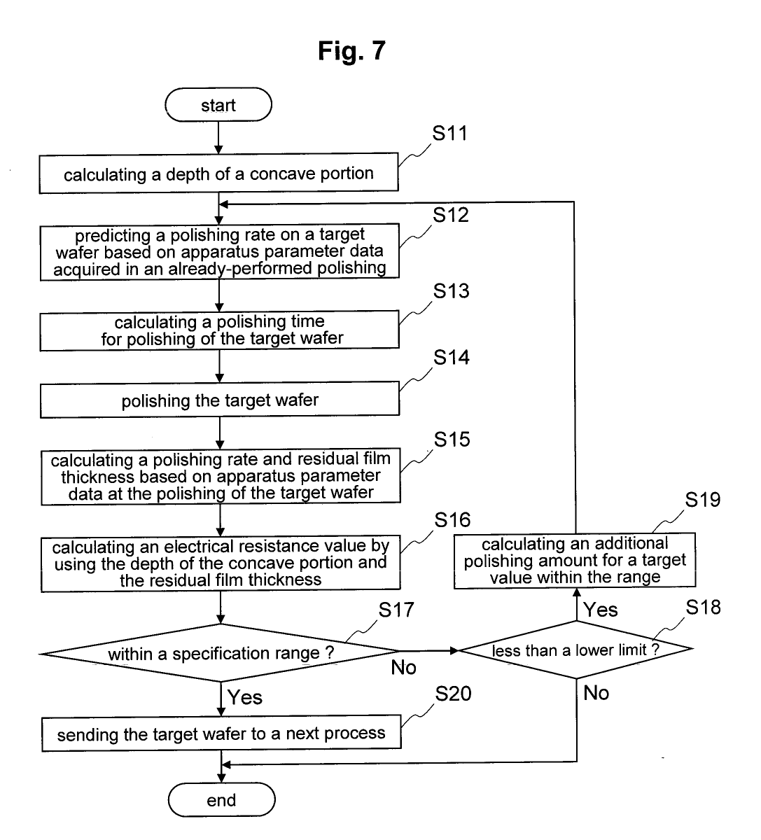

Further, FIG. 7 is a flow chart showing procedures for the method of manufacturing a semiconductor device relating to this embodiment. The APC system 60 starts the procedures before starting to polish a specific wafer (hereafter, referred to as a target wafer) by the CMP apparatus 68c. Furthermore, FIG. 7 shows procedures to be implemented for one target wafer. In other words, the procedures are executed per target wafer.

As shown in FIG. 7, when the procedures are started, first, a depth of a concave portion formed in an interlayer insulating film on the target wafer is calculated by an etching depth calculating unit 63a of the APC system 60 (Step S11 in FIG. 7). The etching depth calculating unit 63a calculates the depth of a concave portion using a value(s) of the apparatus parameter(s) (hereafter, referred to as apparatus parameter data) collected when an etching processing for the target wafer and a concave portion depth calculation expression.

The apparatus parameter data of the etching apparatus 68a is collected and stored by an apparatus parameter collecting unit 62a via a controller of the etching apparatus 68a. The apparatus parameter collecting unit 62a, for example, collects the apparatus parameter data during etching processing, for example, at 1 Hz or greater of sampling rate. Furthermore, the apparatus parameter data collected by the apparatus parameter collecting unit 62a include, for example, values, such as high-frequency power, reflection wave power, Vpp voltage measured by an electrode where a wafer is placed (range between a maximum value and a minimum value of a cycle-varying wafer mounting electrode voltage), Vdc voltage (self-bias voltage), gas pressure, valve opening, plasma emission intensity, etc.

Further, the concave portion depth calculation expression is an expression showing a corresponding relationship between the apparatus parameters of the etching apparatus 68a and the depth of the concave portion formed in the interlayer insulating film, and is pre-acquired and registered in the etching depth calculating unit 63a. In this embodiment, the concave depth calculating expression expressed with the expression (3) is pre-prepared using a plurality of data composed of a statistical value of the apparatus parameters acquired during a specific period within the etching processing period and the depth of the concave portion formed by the etching processing.

The etching depth calculating unit 63a calculates the depth of the concave portion, for example, by substituting a statistical value which is calculated from the apparatus parameter data acquired during a specific period within the etching processing period for the target wafer into the concave portion depth calculating expression. Furthermore, the specific period is a period excluding a period including inappropriate apparatus parameter data for the calculation of the statistical value. For example, in a case that the etching apparatus 68a is a plasma etching apparatus, the period including the inappropriate apparatus parameter data for the calculation of the statistical value is a period when plasma is unstable at a time of start of etching processing or at a time of completion of etching processing. When there is no period including the inappropriate apparatus parameter data for the calculation of the statistical value, the specific period may be matched with the period where etching processing is implemented to the target wafer.

Next, a polishing rate calculating unit 66 of the APC system 60 predicts a polishing rate when implementing to polish the target wafer by the CMP apparatus 68c (Step S12 in FIG. 7). The polishing rate calculating unit 66 predicts a polishing rate from the apparatus parameter data showing the latest apparatus condition of the CMP apparatus 68c and a polishing rate calculating expression. Here, the apparatus parameter data showing the latest apparatus condition is the latest acquired apparatus parameter data at a time of calculating the polishing rate by the polishing rate calculating unit 66. For example, the apparatus parameter data acquired in the polishing process completed in the CMP apparatus 68c immediately before the calculation of the polishing rate of the target wafer is the latest acquired apparatus parameter data.

The apparatus parameter data of the CMP apparatus 68c is collected and stored by an apparatus parameter collecting unit 62c via a controller of the CMP apparatus 68c. The apparatus parameter collecting unit 62c collects the apparatus parameter data during polishing processing, for example, at 1 Hz or greater of sampling rate. Furthermore, the apparatus parameter data collected by the apparatus parameter collecting unit 62c include, for example, values, such as polishing load for a wafer, pressure of wafer pressuring head, current of a motor to drive a platen, load of a dresser, current of a motor to drive a dresser, slurry flow rate, pad surface current, etc.

Further, the polishing rate calculation expression is an expression showing a corresponding relationship between the apparatus parameters of the CMP apparatus 68c and the polishing rate, and is pre-acquired and registered in the polishing rate calculating unit 66. In this embodiment, the polishing rate calculating expression expressed with the expression (3) is pre-prepared using a plurality of data composed of a statistical value of the apparatus parameters acquired during a specific period within the polishing processing period and a polishing amount by the polishing processing. The polishing rate calculating unit 66 calculates the polishing rate, for example, by substituting a statistical value which is calculated from the apparatus parameter data acquired during a specific period within the apparatus parameter data showing the latest apparatus condition into the polishing rate calculating expression. Furthermore, in a case that the CMP apparatus 68c comprises a plurality of polishing platens for implementing polishing in different stages, the polishing rate calculation expression is obtained for each polishing platen. The different stages mean, for example, polishing halfway a copper film, polishing to a boundary surface between a copper film and a barrier film and polishing of barrier film.

Subsequently, a polishing time determining unit 67 calculates a polishing time required for removal of a copper plating film (and barrier film) deposited onto the interlayer insulating film from the copper plating film thickness deposited by the plating apparatus 68b and the polishing rate calculated by the polishing rate calculating unit 66 (Step S13 in FIG. 7). This polishing time includes an over polishing time for the purpose of completely removing a conductive film on a surface of the target wafer. Further, the copper plating film thickness is a copper plating film thickness measured by the film thickness measuring apparatus 69b. When the copper plating film thickness of all wafers is measured, the copper plating film thickness measured for the target wafer is used for the calculating of the polishing time. However, it is reality to measure the copper plating film thickness of only a part of wafers selected from the same lot. In this case, the copper plating film thickness measured in the lot where the target wafer belongs (if a plurality of wafers are measured, the average value) is used for the calculation of the polishing time. Furthermore, a predicted value of the polishing rate to be used for the calculation of the polishing time is not a value for predicting each target wafer. Therefore, when the polishing time is calculated by using the copper film thickness measured in the lot where the target wafer belongs, each polishing time calculated for all wafers in the lot where the target wafer belongs is the same value. Furthermore, in a case that the CMP apparatus 68c comprises a plurality of polishing platens for implementing the polishing in the different stages, the polishing time is obtained for each polishing platen. In this case, in addition to the copper plating film thickness, it is preferable to measure the barrier film thickness, as well. The polishing time determining unit 67 enters the calculated polishing time into a controller of the CMP apparatus 68c.

The CMP apparatus 68c where the polishing time is entered implements the polishing according to the calculated polishing time for the target wafer at a time of polishing the target wafer (Step S14 in FIG. 7). Even in this polishing, the apparatus parameters are collected by the apparatus parameter collecting unit 62c. The apparatus parameter collecting unit 62c stores the collected apparatus parameters in association with wafer identification information, such as wafer ID.

When polishing of the target wafer is completed in the CMP apparatus 68c, the polishing rate calculating unit 66 calculates a polishing rate from the apparatus parameter data acquired at the time of polishing the target wafer and the polishing rate calculation expression. The polishing rate calculated as described above is a calculated value of the polishing rate at the time of polishing implemented to the target wafer. A residual film thickness calculating unit 63b calculates a post-polishing interlayer insulating film thickness (hereafter, referred to as a post-polishing residual film thickness) from the calculated value of the polishing rate and the measured copper plating film thickness (Step S15 in FIG. 7). Here, since the calculated value of the polishing rate is calculated using the apparatus parameter data measured per target wafer, the post-polishing residual film thickness can be individually calculated per target wafer.

Subsequently, an electrical characteristic computing unit 64 predicts an electrical resistance value by substituting the depth of the concave portion calculated by the etching depth calculating unit 63a and the post-polishing residual film thickness calculated by the residual film thickness calculating unit 63b into an electrical characteristic prediction expression (Step S16 in FIG. 7). Since this electrical resistance value is calculated using the depth of the concave portion calculated for the target wafer and the post-polishing residual film thickness calculated for the target wafer, an individual value per target wafer shall be calculated. The electrical characteristic computing unit 64 enters the calculated electrical resistance value into a determining unit 70. Furthermore, the electrical characteristic prediction expression is pre-acquired and registered in the electrical characteristic computing unit 64. The electrical characteristic prediction expression is an expression showing a corresponding relationship between the depth of the concave portion, the post-polishing residual film thickness and the electrical resistance. Furthermore, the electrical characteristic prediction expression may contain other diffusion parameters, such as opening width, as in the expression (1); however, it is simplified for explanation.

The determining unit 70 where the electrical resistance value is entered determines whether the entered electrical resistance value is within a predetermined specification range (Step S17 in FIG. 7). When determining that the electrical resistance value calculated for the target wafer is within the specification range, the determining unit 70 notifies an instruction to send the target wafer to a next process to a manufacturing execution system (MES) 100 for managing a production line of the semiconductor device. With this notification, the target wafer is sent to the next process by the MES 100 (Step S20 in FIG. 7).

In the meantime, when determining that the calculated electrical resistance value for the target wafer is beyond the specification range, the determining unit 70 further determines whether the calculated electrical resistance value is less than a lower limit value of the specification range (Step S17 No, S18 in FIG. 7). This is because even if the calculated electrical resistance value is beyond the specification range, in a case that the value is less than the lower limit value, the electrical resistance is low and the electrical resistance value is increased by implementing additional polishing and the electrical resistance value within the specification range can be obtained. When determining that the calculated electrical resistance value for the target wafer is low resistance beyond the specification range, the determining unit 70 instructs the electrical characteristic computing unit 64 to calculate an additional polishing amount (Step S18 Yes in FIG. 7). The electrical characteristic computing unit 64 that has received the instruction calculates the post-polishing insulating film thickness to be a predetermined electrical resistance value (target value) within the specification range pre-registered in a target value memory unit 65 using the electrical characteristic prediction expression, and obtains the additional polishing amount by calculating a difference between this post-polishing insulating film thickness and the post-polishing residual film thickness (Step S19 in FIG. 7). The electrical characteristic computing unit 64 enters the calculated additional polishing amount to the polishing time determining unit 67. The polishing time determining unit 67 that has received the additional polishing amount uses the additional polishing amount instead of the copper plating film thickness, and calculates an additional polishing time from the additional polishing amount and the calculated polishing rate calculated based on the latest apparatus parameter data by the CMP apparatus 68c, and the polishing of the target wafer is implemented according to the additional polishing time by the CMP apparatus 68c (Steps S12 to S14 in FIG. 7). With this design, a part of wafers determined as out of the specification range can be recovered. Hereafter, the procedures shown in Steps S15 to S17 are executed. Further, when determining that the calculated electrical resistance value for the target wafer is high resistance beyond the specification range, the determining unit 70 ends the procedures without notifying the instruction to send the target wafer to the next process to the MES 100 (Step S18 No in FIG. 7). Consequently, the target wafers whose electrical resistance value is a high resistance beyond the specification range will never be sent to the next process.

As described above, according to this embodiment, an electrical characteristic is predicted at a time of completing the polishing process, only a wafer whose electrical characteristic is within the specification range, i.e., only a wafer having constant electrical characteristic can be sent to a next process. As a result, the electrical characteristics of the semiconductor devices formed on different wafers can become constant, and a decrease in the production yield caused by the apparatus condition fluctuations can be inhibited. Further, wafers whose electrical characteristic is out of the specification range can be determined without measuring the electrical characteristic, and the implementation of a subsequent process to the wafers whose electrical characteristic is out of the specification range can be prevented. In addition, a part of irregular wafers can be recovered.

### Third Embodiment

In the second embodiment, since the electrical resistance value is predicted after polishing is implemented and the determination is conducted based upon the predicted electrical resistance value, wafers whose electrical resistance value is beyond the specification range and is high resistance cannot be recovered. Then, in a third embodiment, a configuration to enable a prevention of occurrence of such wafer is explained.

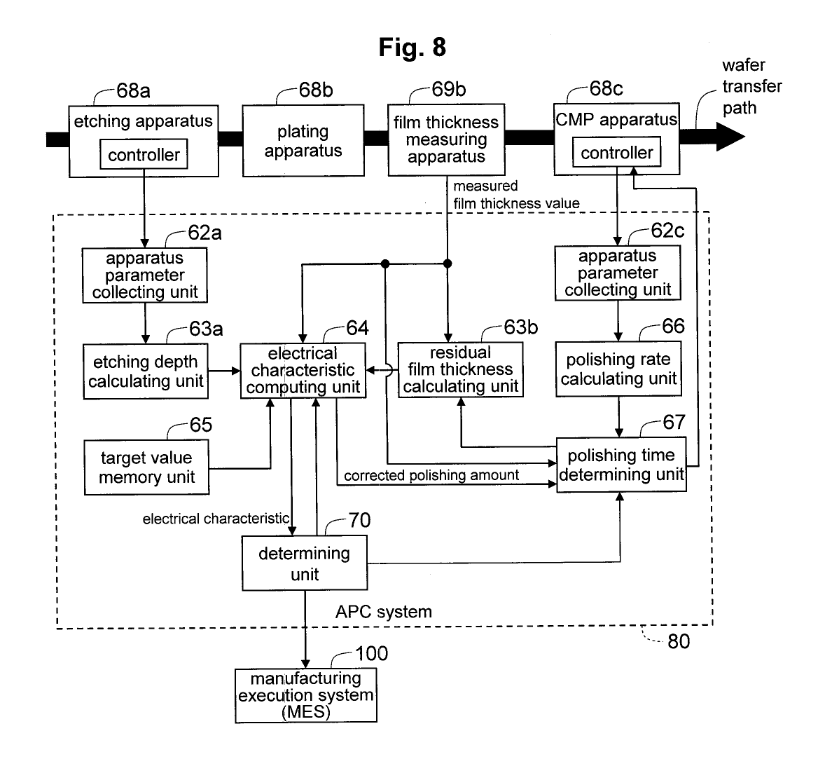

FIG. 8 is a configuration diagram showing a semiconductor manufacturing system to realize a method of manufacturing a semiconductor device in this embodiment. As shown in FIG. 8, although an APC system 80 of this semiconductor manufacturing system has the same components as those in the APC system 60 described in the second embodiment, a data transmission path and a transmission order are different as described below. According to this configuration, the APC system 80 in this embodiment predicts the electrical resistance value of a target wafer before polishing by the CMP apparatus 68c. Furthermore, hereafter, any components providing the same effect as those in the second embodiment are referred to by the same reference numbers, and detailed explanations will be omitted.

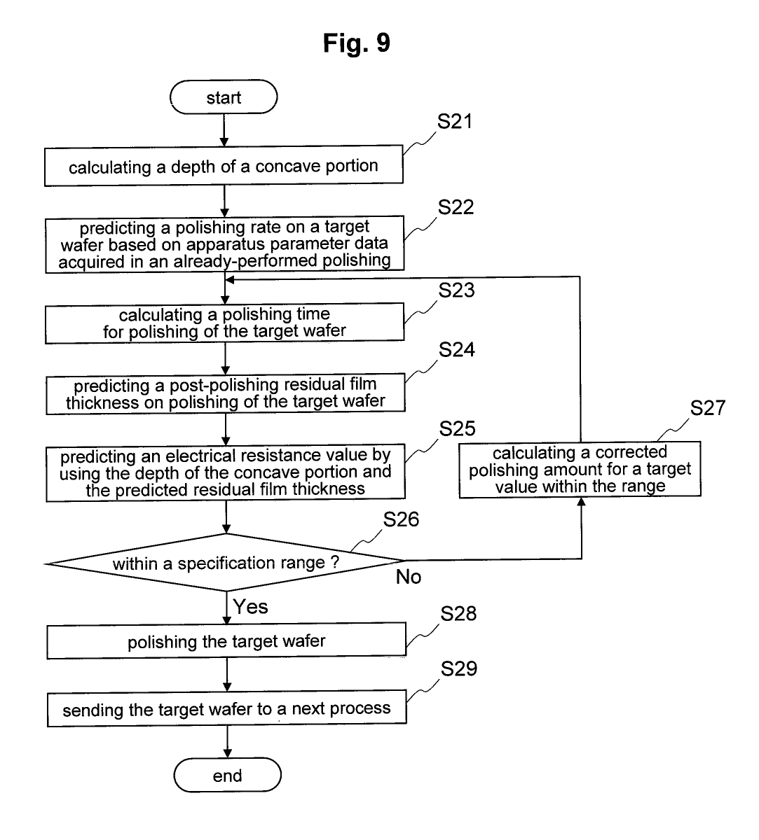

FIG. 9 is a flow chart showing procedures for the method of manufacturing a semiconductor device relating to this embodiment. The APC system 80 starts the procedures before starting to polish a target wafer by the CMP apparatus 68c. Furthermore, FIG. 9 shows procedures to be implemented for one target wafer. In other words, the procedures are executed per target wafer.

As shown in FIG. 9, when the procedures are started, first, the etching depth calculating unit 63a of the APC system 80 calculates a depth of a concave portion formed in an interlayer insulating film on the target wafer in the etching apparatus 68a (Step S21 in FIG. 9). Next, the polishing rate calculating unit 66 predicts a polishing rate when implementing to polish the target wafer by the CMP apparatus 68c (Step S22 in FIG. 9). Further, the polishing time determining unit 67 calculates a polishing time from the copper plating film thickness deposited by the plating apparatus 68b and the polishing rate calculated by the polishing rate calculating unit 66 (Step S23 in FIG. 9). Since the procedures shown in Steps S21 to S23 are the same as Steps S11 to S13 explained in the second embodiment, any explanations herein are omitted. Furthermore, in this embodiment, the polishing time determining unit 67 enters the calculated polishing time into the residual film thickness calculating unit 63b.

The residual film thickness calculating unit 63b where the polishing time is entered calculates the post-polishing residual film thickness of the target wafer (Step S24 in FIG. 9). The residual film thickness calculating unit 63b enters the calculated post-polishing residual film thickness into the electrical characteristic computing unit 64. Furthermore, as described above, when the polishing time is calculated by using the copper plating film thickness measured for a lot where the target wafer belongs, each polishing time calculated for all wafers in the lot where the target wafer belongs is the same value. In this case, each post-polishing residual film thickness calculated by the residual film thickness calculating unit 63b is the same value for all wafers in the lot where the target wafer belongs.

Subsequently, the electrical characteristic computing unit 64 predicts an electrical resistance value by substituting the depth of the concave portion calculated by the etching depth calculating unit 63a and the post-polishing residual film thickness calculated by the residual film thickness calculating unit 63b into the electrical characteristic prediction expression (Step S25 in FIG. 9). Since this electrical resistance value is calculated using the depth of the concave portion calculated for the target wafer, an individual value per target wafer shall be calculated. The electrical characteristic computing unit 64 enters the calculated electrical resistance value into the determining unit 70. Furthermore, in the electrical characteristic computing unit 64, the electrical characteristic prediction expression explained in the second embodiment is pre-registered.

The determining unit 70 where the electrical resistance value is entered determines whether the entered electrical resistance value is within the predetermined specification range (Step S26 in FIG. 9). When determining that the electrical resistance value calculated for the target wafer is within the specification range, the determining unit 70 instructs the polishing time determining unit 67 to execute the polishing at the polishing time calculated in Step S23; concurrently, notifies the MES 100 to send the target wafer to the next process (Step S26 Yes in FIG. 9). The polishing time determining unit 67 receiving the instruction enters the polishing time calculated in Step S23 into the controller of the CMP apparatus 68c. The CMP apparatus 68c where the polishing time is entered implements to polish the target wafer according to the calculated polishing time when polishing the target wafer (Step S28 in FIG. 9). Then, after the polishing is completed, the target wafer is sent to the next process by the MES 100 (Step S29 in FIG. 9).

In the meantime, when determining that the calculated electrical resistance value for the target wafer is beyond the specification range, the determining unit 70 instructs the electrical characteristic computing unit 64 to calculate an appropriate polishing amount (corrected polishing amount) (Step S26 No in FIG. 9). The electrical characteristic computing unit 64 that has received the instruction calculates the post-polishing insulating film thickness to be a predetermined electrical resistance value (target value) within the specification range pre-registered in the target value memory unit 65 using the electrical characteristic prediction expression, and calculates the corrected polishing amount from this post-polishing insulating film thickness and the copper plating film thickness (Step S27 in FIG. 9). With this design, the greater corrected polishing amount than the polishing amount before the correction is calculated in a case that the electrical resistance value is less than the lower limit value of the specification range, and the smaller corrected polishing amount than the polishing amount before the correction is calculated in a case that the electrical resistance value exceeds an upper limit value of the specification range.

The electrical characteristic computing unit 64 enters the calculated corrected polishing amount into the polishing time determining unit 67. The polishing time determining unit 67 that has received the corrected polishing amount calculates the polishing time by using the corrected polishing amount (Step S23 in FIG. 9). Hereafter, the procedures shown in Steps S24 to S26 are executed, and when the predicted value of the electrical resistance value is within the specification range, the polishing for the target wafer is executed by the CMP apparatus 68c (Step S28 in FIG. 9).

As explained above, in this embodiment, unlike the second embodiment, when the predicted value of the electrical resistance value is within the specification range, the polishing is executed. Therefore, since adequacy of the polishing time is determined before the execution of polishing, wafers whose electrical resistance value exceeds an upper limit of the specification range, which are impossible to be recovered in the second embodiment, can be recovered. Consequently, according to this embodiment, the occurrence of wafers having an irregular electrical resistance value can be prevented; concurrently, the electrical characteristics of semiconductor devices formed on different wafers can become constant.

Furthermore, in the explanation above, when re-calculating the polishing time using the corrected polishing amount, the polishing rate calculated in Step S22 is used. This is because it is an extremely short time requiring for calculating the correct polishing amount after calculating the polishing time in Step S23 and the polishing rate calculated in Step S22 appears to be the latest polishing rate. If there is any possibility that the apparatus conditions of the polishing apparatus may fluctuate after the polishing time is calculated in Step S23 until the corrected polishing amount is calculated, the latest polishing rate is re-calculated and the polishing time may be re-calculated using the latest polishing rate and the corrected polishing amount.

### Fourth Embodiment

In the configuration of the third embodiment, supposedly, if there is great divergence between the predicted electrical resistance value and the actual electrical resistance value of a polished wafer, there is a possibility that some wafers having an irregular electrical resistance value may be sent to the subsequent process. Then, in a fourth embodiment, it is designed to confirm whether the prediction of the electrical resistance value can be accurately implemented by modifying the configuration in the third embodiment.

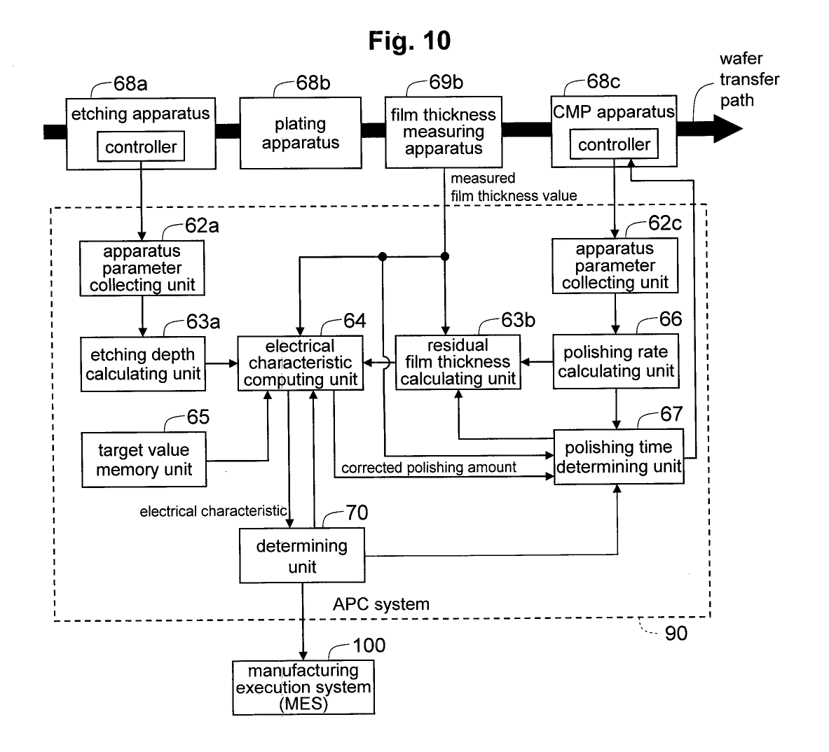

FIG. 10 is a configuration diagram showing a semiconductor manufacturing system to realize a method of manufacturing a semiconductor device in this embodiment. As shown in FIG. 10, although an APC system 90 of this semiconductor manufacturing system has the same components as those in the APC system 80 described in the third embodiment, a data transmission path and a transmission order are different as described below. According to this configuration, the APC system 90 in this embodiment can confirm the adequacy of the predicted electrical resistance value after the polishing is implemented by the CMP apparatus 68c. Furthermore, hereafter, any components providing the same effect as those in the second embodiment are referred to by the same reference numbers, and detailed explanations will be omitted.

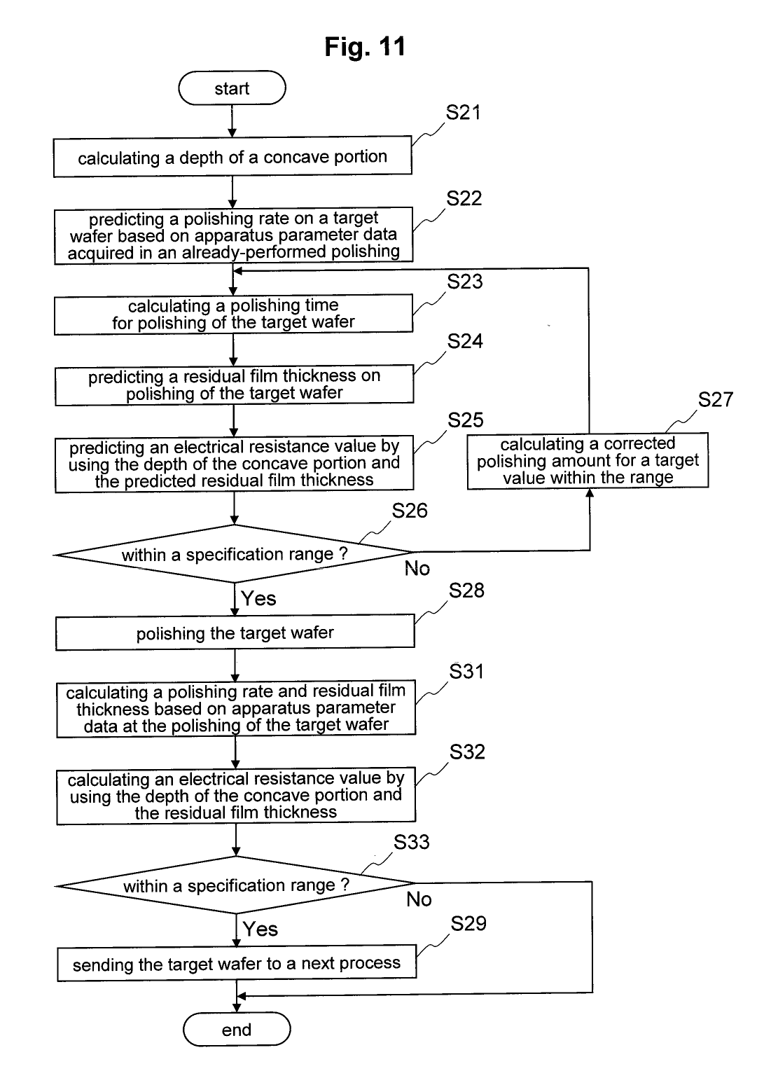

FIG. 11 is a flow chart showing procedures for the method of manufacturing a semiconductor device relating to this embodiment. As shown in FIG. 11, the procedures in this embodiment contain all procedures shown in Steps S21 to S29 explained in the third embodiment. Then, in this embodiment, in the procedures explained in the third embodiment, procedures mentioned below are executed after the polishing is implemented. Furthermore, in this embodiment, unlike the third embodiment, when determining that the electrical resistance value calculated for the target wafer in Step S26 is within the specification range, although the determining unit 70 instructs the polishing time determining unit 67 to execute the polishing at the polishing time calculated in Step S23, it does not notify any instruction to the MES 100 for sending the target wafer to the next process.

When the polishing of the target wafer is completed by the CMP apparatus 68c (Step S28 in FIG. 11), the polishing rate calculating unit 66 calculates a calculated value of the polishing rate from the apparatus parameter data acquired at a time of polishing the target wafer and the above mentioned polishing rate calculation expression. The residual film thickness calculating unit 63b calculates the post-polishing residual film thickness of the target wafer according to the calculated value of the polishing rate and the measured copper plating film thickness (Step S31 in FIG. 11). Furthermore, the apparatus parameter data at the time of polishing to be used for the calculation of the polishing rate is collected and stored by the apparatus parameter collecting unit 62c when polishing the target wafer as explained in the second embodiment.

Subsequently, the electrical characteristic computing unit 64 substitutes the depth of the concave portion calculated by the etching depth calculating unit 63a in Step S21 and the post-polishing residual film thickness calculated by the residual film thickness calculating unit 63b into the electrical characteristic prediction expression, and predicts the electrical resistance value (Step S32 in FIG. 11). The electrical characteristic computing unit 64 enters the calculated electrical resistance value into the determining unit 70. Furthermore, the electrical characteristic prediction expression explained in the second embodiment is pre-registered in the electrical characteristic computing unit 64.

The determining unit 70 where the electrical resistance value is entered determines whether the entered electrical resistance value is within the predetermined specification range (Step S33 in FIG. 11). When determining that the electrical resistance value calculated for the target wafer is within the specification range, the determining unit 70 notifies the MES 100 to send the target wafer to the next process (Step S33 Yes in FIG. 11). In this case, the target wafer is sent to the next process by the MES 100 (Step S29 in FIG. 11). Further, when determining that the electrical resistance value calculated for the target wafer is beyond the specification range, the determining unit 70 ends the procedures without notifying the MES 100 to send the target wafer to the next process (Step S33 No in FIG. 11). Consequently, any target wafers whose electrical resistance value is beyond the specification range will never be sent to the next process.

As explained above, according to this embodiment, in addition to the effect of the third embodiment, it prevents wafers having an irregular electrical resistance value from being sent to the subsequent process. In addition, in this embodiment, the electrical resistance value to be used for the determination in Step S33, unlike the third embodiment, is calculated using the post-polishing residual film thickness calculated according to the apparatus parameter data acquired at the time polishing the target wafer. In other words, since the electrical resistance value is calculated using unique depth of the concave portion calculated per target wafer and unique post-polishing residual film thickness calculated per target wafer, the value is highly accurate that the electrical resistance value used for the determination in Step S26 of the third embodiment. Therefore, in this embodiment, quality determination of the electrical resistance value can be implemented with extremely high accuracy.

### Fifth Embodiment

In a fifth embodiment, a configuration enabling the recover of wafers having an irregular electrical resistance value by modifying the configuration of the fourth embodiment. Since a configuration of a semiconductor manufacturing system to realize a method of manufacturing a semiconductor device in this embodiment is substantially the same as the configuration explained in the fourth embodiment, any explanation herein will be omitted. Furthermore, the point of different in the configuration from the fourth embodiment is a point where the electrical characteristic computing unit 64 further enters the calculated additional polishing amount to the polishing time determining unit 67 described below.

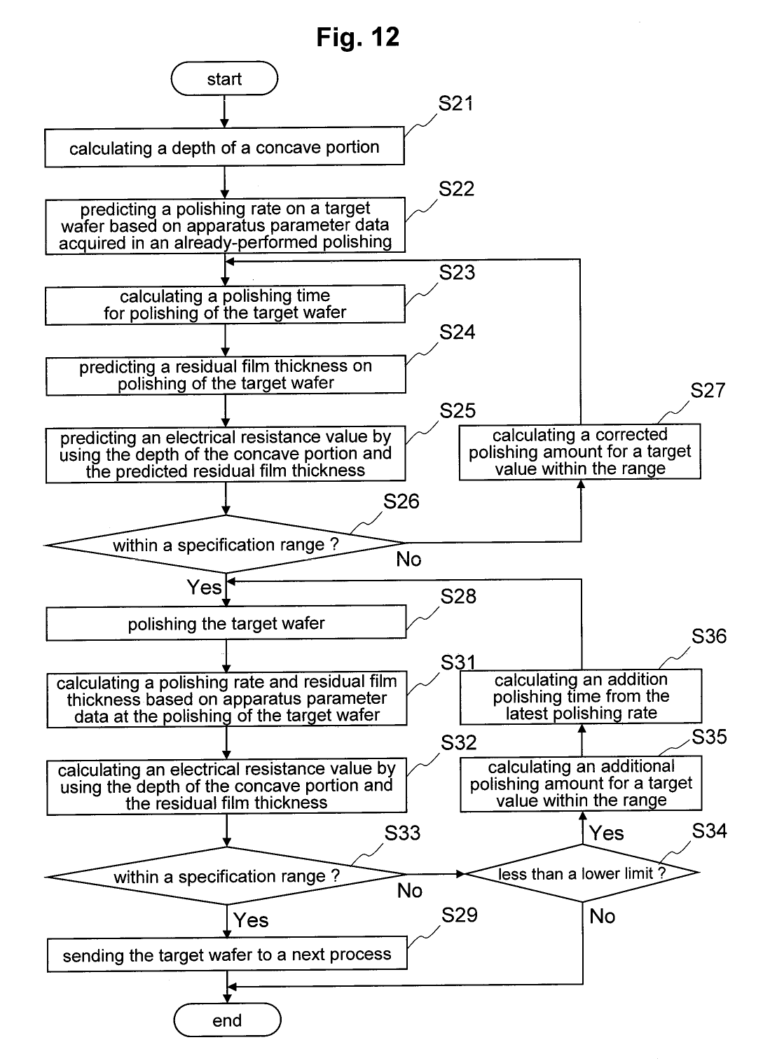

FIG. 12 is a flow chart showing procedures for the method of manufacturing a semiconductor device relating to this embodiment. As shown in FIG. 12, the procedures in this embodiment contain all procedures shown in Steps S21 to S29 and S31 to S33 explained in the fourth embodiment. Then, in this embodiment, in the procedures explained in the fourth embodiment, procedures mentioned below are executed after the confirmation of the electrical resistance value to be implemented after the polishing.

In the determination of Step S33, when determining that the electrical resistance value calculated for the target wafer is beyond the specification range, the determining unit 70 further determines that the calculated electrical resistance value is less than the lower limit value of the specification range (Steps S33 No, S34 in FIG. 12). When determining that the electrical resistance value calculated for the target wafer is a low resistance beyond the specification range, the determining unit 70 instructs the electrical characteristic computing unit 64 to calculate an addition polishing amount (Step S34 Yes in FIG. 12). The electrical characteristic computing unit 64 that has received the instruction calculates the post-polishing insulating film thickness to be a predetermined electrical resistance value (target value) within the specification range pre-registered in the target value memory unit 65 using the electrical characteristic prediction expression, and obtains the addition polishing amount by calculating a difference between this post-polishing insulating film thickness and the post-polishing residual film thickness calculated in Step S31 (Step S35 in FIG. 12). The electrical characteristic computing unit 64 enters the calculated additional polishing amount to the polishing time determining unit 67. The polishing time determining unit 67 that has received the additional polishing amount calculates an addition polishing time from the additional polishing amount and the polishing rate calculated based on the latest apparatus parameter data in the CMP apparatus 68c (Step S36 in FIG. 12). The polishing time determining unit 67 enters the calculated addition polishing time to the controller of the CMP apparatus 68c. Then, the CMP apparatus 68c polishes the target wafer at the additional polishing time (Step S28 in FIG. 12). With this design, a part of wafers that have been determined as irregular can be recovered. Hereafter, the procedures shown in Steps S31 to S33 explained in the fourth embodiment are executed.

Further, when determining that the electrical resistance value calculated for the target wafer is high resistance beyond the specification range, the determining unit 70 ends the procedures without notifying the instruction to send the target wafer to the next process to the MES 100 (Step S34 No in FIG. 12).

As explained above, according to this embodiment, in addition to the effect of the fourth embodiment, a part of wafers determined as having an irregular electrical resistance value can be recovered. In other words, compared to the fourth embodiment, variations of the electrical resistance values can be further reduced. Further, even if the prediction accuracy is insufficient, variations of the electrical resistance values among wafers can be inhibited by setting a narrower specification range than the fourth embodiment, and it also becomes possible to adjust the electrical resistance value to a median value within the specification range.

As explained above, according to the present invention, a method of manufacturing a semiconductor device that predicts electrical characteristics with high accuracy and controls the electrical characteristics to be uniform using the prediction expression can be provided.

Furthermore, the present invention shall not be limited to the embodiments, but it is variously modifiable and applicable without departing from the scope of the technical concept of the present invention. For example, in the above embodiments, parameters to define a geometric configuration of patterns composing a semiconductor device are adopted as the diffusion parameters. However, the diffusion parameters can be film quality of a film deposited onto a semiconductor substrate (for example, permittivity of an insulating film) or a number of particles on a semiconductor substrate. Further, each unit implementing the computing in the APC systems 60, 80 and 90 are can be realized by, for example, an exclusive-use calculation circuit, or hardware having a processor and memories such as RAM (random access memory) or ROM (read only memory), etc. and software stored in the memories and operating on the processor.

According to the present invention, since the electrical characteristics can be constant, in manufacturing processes for a semiconductor device with a small electrical behavior margin, a production yield can be maintained. Therefore, it is extremely useful as a method of manufacturing a semiconductor device where minute rules are applied.

What is claimed is:

1. A method of manufacturing a semiconductor device manufactured through a plurality of processes, comprising the steps of:
acquiring values of diffusion parameters of a semiconductor device in a middle of manufacturing of the semiconductor device;
calculating a target value of another diffusion parameter of the semiconductor device, in order to control an electrical characteristic of the semiconductor device using APC technology, by substituting the acquired values of the diffusion parameters and a desired value of the electrical characteristic into a predetermined electrical characteristic prediction expression showing a corresponding relationship between the electrical characteristic and a plurality of types of diffusion parameters, a value of the another diffusion parameter being determined by a processing implemented in a subsequent process;
determining processing conditions for the processing implemented in the subsequent process to realize the target value; and
implementing the processing to the semiconductor device in the subsequent process under the determined processing conditions.

2. A method of manufacturing a semiconductor device according to claim 1, wherein, in the step of acquiring the values of the diffusion parameters of the semiconductor device, the value of at least one diffusion parameter is acquired by substituting values of apparatus parameters of a manufacturing apparatus acquired in a processing of the semiconductor device in the manufacturing apparatus into a predetermined diffusion parameter calculating expression showing a corresponding relationship between the at least one diffusion parameter and the apparatus parameters, a value of the at least one diffusion parameter being determined by the processing implemented in the manufacturing apparatus.

3. A method of manufacturing a semiconductor device according to claim 1, wherein the plurality of processes comprises the steps of:
forming a concave portion in an insulating film formed on a semiconductor substrate;
depositing a conductive film on the insulating film where the concave portion is formed and embedding the concave portion with the conductive film; and
forming a wiring by removing the conductive film on the insulating film except for the concave portion using polishing, and wherein
the diffusion parameters of which values are acquired include a depth of the concave portion, an opening width of the concave portion and a film thickness of the insulating film before the polishing, the electrical characteristic includes an electrical resistance of the wiring, the another diffusion parameter of which value is determined by the processing in the subsequent process includes a film thickness of the insulating film after the polishing and the processing conditions include a polishing time.

4. A method of manufacturing a semiconductor device according to claim 2, wherein the plurality of processes comprises the steps of:
forming a concave portion in an insulating film formed on a semiconductor substrate;
depositing a conductive film on the insulating film where the concave portion is formed and embedding the concave portion with the conductive film; and
forming a wiring by removing the conductive film on the insulating film except for the concave portion using polishing, and wherein
the diffusion parameters of which values are acquired include a depth of the concave portion, an opening width of the concave portion and a film thickness of the insulating film before the polishing, the electrical characteristic includes an electrical resistance of the wiring, the diffusion parameter of which value is determined by the processing in the subsequent process includes a film thickness of the insulating film after the polishing and the processing conditions includes a polishing time.

5. A method of manufacturing a semiconductor device manufactured through a plurality of processes including the steps of: forming a concave portion in an insulating film formed on a semiconductor substrate using an etching apparatus; depositing a conductive film on the insulating film where the concave portion is formed and embedding the concave portion with the conductive film; and removing the conductive film on the insulating film except for the concave portion using a polishing apparatus, the method comprising the steps of:
acquiring values of apparatus parameters of the etching apparatus when a specific semiconductor substrate is processed in the etching apparatus;
calculating a depth of a concave potion formed in an insulating film on the specific semiconductor substrate by substituting the acquired values of the apparatus parameters into a predetermined concave portion depth calculation expression showing a corresponding relationship between the apparatus parameters of the etching apparatus and the depth of the concave portion formed in the insulating film;
calculating a polishing rate by substituting values of apparatus parameters of the polishing apparatus acquired in an already-implemented polishing in the polishing apparatus into a predetermined polishing rate calculation expression showing a corresponding relationship between the apparatus parameters of the polishing apparatus and the polishing rate;
calculating a polishing time to be applied to the specific semiconductor substrate in the polishing apparatus from the calculated polishing rate and a film thickness of a conductive film deposited onto the insulating film on the specific semiconductor substrate;
polishing the specific semiconductor substrate according to the calculated polishing time in the polishing apparatus and acquiring values of the apparatus parameters of the polishing apparatus at a time of the polishing of the specific semiconductor substrate;
calculating a post-polishing residual film thickness of the insulating film on the specific semiconductor substrate from the film thickness of the conductive film deposited onto the insulating film on the specific semiconductor substrate and a polishing rate calculated by substituting the values of the apparatus parameters of the polishing apparatus acquired in the polishing of the specific semiconductor substrate into the polishing rate calculation expression;
calculating an electrical resistance value of a wiring formed on the specific semiconductor substrate by substituting the calculated post-polishing residual film thickness on the specific semiconductor substrate and the calculated depth of the concave portion on the specific semiconductor substrate into a predetermined electrical characteristic prediction expression showing a corresponding relationship among the depth of the concave portion, the post-polishing residual film thickness and the electrical resistance;
determining whether the calculated electrical resistance value is within a predetermined specification range; and
polishing the specific semiconductor substrate according to an additional polishing amount in the polishing apparatus in a case that the calculated electrical resistance value is low resistance beyond the specification range as a result of the determination, the additional polishing amount being calculated based on the electrical characteristic prediction expression.

6. A method of manufacturing a semiconductor device manufactured through a plurality of processes including the steps of: forming a concave portion in an insulating film formed on a semiconductor substrate using an etching apparatus; depositing a conductive film on the insulating film where the concave portion is formed and embedding the concave portion with the conductive film; and removing the conductive film on the insulating film except for the concave portion using a polishing apparatus, the method comprising the steps of:
acquiring values of apparatus parameters of the etching apparatus when a specific semiconductor substrate is processed in the etching apparatus;
calculating a depth of a concave potion formed in an insulating film on the specific semiconductor substrate by substituting the acquired values of the apparatus parameters into a predetermined concave portion depth calculation expression showing a corresponding relationship between the apparatus parameters of the etching apparatus and the depth of the concave portion formed in the insulating film;
calculating a polishing rate by substituting values of apparatus parameters of the polishing apparatus acquired in an already-implemented polishing in the polishing apparatus into a predetermined polishing rate calculation expression showing a corresponding relationship between the apparatus parameters of the polishing apparatus and the polishing rate;
calculating a polishing time to be applied to the specific semiconductor substrate in the polishing apparatus from the calculated polishing rate and a film thickness of a conductive film deposited onto the insulating film on the specific semiconductor substrate;
predicting a post-polishing residual film thickness of the insulating film on the specific semiconductor substrate from the calculated polishing rate and the film thickness of the conductive film deposited onto the insulating film on the specific semiconductor substrate;
predicting an electrical resistance value of a wiring to be formed on the specific semiconductor substrate in a case of applying the calculated polishing time by substituting the predicted post-polishing residual film thickness on the specific semiconductor substrate and the calculated depth of the concave portion on the specific semiconductor substrate into a predetermined electrical characteristic prediction expression showing a corresponding relationship among the depth of the concave portion, the post-polishing residual film thickness and the electrical resistance;
determining whether the predicted electrical resistance value is within a predetermined specification range; and
polishing the specific semiconductor substrate according to the calculated polishing time in the polishing apparatus in a case that the predicted electrical resistance value is within the specification range as a result of the determination, and polishing the specific semiconductor substrate according to a newly calculated polishing time in the polishing apparatus in a case that the predicted electrical resistance value is beyond the specification range as a result of the determination, the newly calculated polishing time being calculated from the polishing rate and a corrected polishing amount to realize an electrical resistance value within the specification range, the corrected polishing amount calculated based on the electrical characteristic prediction expression.

7. A method of manufacturing a semiconductor device according to claim 6, further comprising the steps of:
acquiring values of the apparatus parameters of the polishing apparatus at a time of the polishing of the specific semiconductor substrate in the polishing apparatus;
calculating a post-polishing residual film thickness of the insulating film on the specific semiconductor substrate from the film thickness of the conductive film deposited onto the insulating film on the specific semiconductor substrate and a polishing rate newly calculated by substituting the values of the apparatus parameters of the polishing apparatus acquired in the polishing of the specific semiconductor substrate into the polishing rate calculating expression;
calculating an electrical resistance value of a wiring formed on the specific semiconductor substrate by substituting the calculated post-polishing residual film thickness on the specific semiconductor substrate and the calculated depth of the concave portion on the specific semiconductor substrate into the electrical characteristic prediction expression; and
determining whether the electrical resistance value calculated after the polishing is within the predetermined specification range.

8. A method of manufacturing a semiconductor device according to claim 7, further comprising the step of
polishing the specific semiconductor substrate according to an additional polishing amount in the polishing apparatus in a case that the electrical resistance value calculated after the polishing is low resistance beyond the specification range as a result of determining whether the electrical resistance value calculated after the polishing is within the predetermined specification range, the additional polishing amount being calculated based on the electrical characteristic prediction expression.
